(19) United States
(12) Patent Application Publication
(10) Pub. No.: US 2024/0152044 A1
(43) Pub. Date: May 9, 2024

(54) REFLECTIVE MASK BLANK, REFLECTIVE MASK, METHOD OF MANUFACTURING REFLECTIVE MASK BLANK, AND METHOD OF MANUFACTURING REFLECTIVE MASK

(71) Applicant: AGC Inc., Tokyo (JP)

(72) Inventors: Daijiro AKAGI, Tokyo (JP); Hiroaki IWAOKA, Tokyo (JP); Shunya TAKI, Tokyo (JP); Kenichi SASAKI, Tokyo (JP); Ichiro ISHIKAWA, Tokyo (JP); Toshiyuki UNO, Tokyo (JP)

(73) Assignee: AGC Inc., Tokyo (JP)

(21) Appl. No.: 18/411,376

(22) Filed: Jan. 12, 2024

Related U.S. Application Data
(63) Continuation of application No. PCT/JP2022/028800, filed on Jul. 26, 2022.

(30) Foreign Application Priority Data
Jul. 30, 2021 (JP) 2021-125887

(51) Int. Cl. G03F 1/24

(52) U.S. Cl. CPC G03F 1/24

(57) ABSTRACT

A reflective mask blank includes a substrate; a multilayer reflective film that reflects EUV light; a phase shift film that shifts a phase of the EUV light, in this order. An opening pattern is to be formed in the phase shift film. The phase shift film has a refractive index of 0.920 or less with respect to the EUV light, an extinction coefficient of 0.024 or more with respect to the EUV light, a thickness of 50 nm or less, a normalized image log slope of 2.9 or more for a transferred image when a line-and-space pattern is formed on a target substrate, and a tolerance range of a focal depth of the transferred image is 60 nm or less.

### CROSS-REFERENCE TO RELATED APPLICATION

The present application is a continuation application of International Application No. PCT/JP2022/028800, filed Jul. 26, 2022, which claims priority to Japanese Patent Application No. 2021-125887 filed Jul. 30, 2021. The contents of these applications are incorporated herein by reference in their entirety.

### BACKGROUND OF THE INVENTION

### 1. Field of the Invention

The disclosure herein generally relates to a reflective mask blank, a reflective mask, a method of manufacturing a reflective mask blank, and a method of manufacturing a reflective mask.

### 2. Description of the Related Art

Along with the recent miniaturization of semiconductor devices, EUV lithography (EUVL), an exposure technology using Extreme Ultra-Violet (EUV) light, has been developed. The EUV light includes a soft X-ray and a vacuum ultraviolet light, and specifically has a wavelength of 0.2 nm to 100 nm. At present, EUV light with a wavelength of about 13.5 nm is mainly studied.

In the EUVL, a reflective mask is used. The reflective mask includes a substrate, such as a glass substrate, a multilayer reflective film that is formed on the substrate, and a phase shift film formed on the multilayer reflective film. An opening pattern is formed in the phase shift film. In the EUVL, the opening pattern of the phase shift film is transferred to a target substrate, such as a semiconductor substrate. The transferring includes transferring a reduced opening pattern.

Example 1 in Japanese Patent No. 6441012 discloses a phase shift film in which a tantalum (Ta) layer and a molybdenum (Mo) layer are laminated alternately. Tantalum (Ta) has a refractive index of 0.943 and an extinction coefficient of 0.041 (paragraph 0045 of Japanese Patent No. 6441012). Molybdenum (Mo) has a refractive index of 0.921 and an extinction coefficient of 0.006 (paragraph 0046 of Japanese Patent No. 6441012).

Example 4 in Japanese Patent No. 6441012 discloses a phase shift film in which a Ta layer and a ruthenium (Ru) layer are laminated alternately. Ruthenium (Ru) has a refractive index of 0.888 and an extinction coefficient of 0.017 (paragraph 0046 of Japanese Patent No. 6441012).

Example 4 of Japanese Patent No. 6861095 discloses a phase shift film made of a ruthenium-nickel (RuNi) alloy (Ru:Ni=0.65:0.35). The RuNi alloy (Ru:Ni=0.65:0.35) has a refractive index of 0.905 and an extinction coefficient of 0.035.

### SUMMARY OF THE INVENTION

### Problems to be Solved by the Invention

Conventionally, chemical compositions and structures of phase shift films for EUVL have been studied. However, in the case where the opening pattern of the phase shift film includes a logic pattern, in which holes and L/S (line-and-space) are mixed, sufficient studies have not been performed.

An aspect of the present disclosure provides a technique for improving an accuracy in transferring a line-and-space pattern from a reflective mask to a target substrate using EUV light.

### Means for Solving the Problem

According to an aspect of the present disclosure, a reflective mask blank includes a substrate; a multilayer reflective film that reflects EUV light; and a phase shift film that shifts a phase of the EUV light, the substrate the multilayer reflective film, and the phase shift film being arranged in this order. An opening pattern is to be formed in the phase shift film. The phase shift film has a refractive index of 0.920 or less with respect to the EUV light, an extinction coefficient of 0.024 or more with respect to the EUV light, a thickness of 50 nm or less, a normalized image log slope of 2.9 or more for a transferred image when a line-and-space pattern is formed on a target substrate, and a tolerance range of a focal depth of the transferred image of 60 nm or less.

### Effects of the Invention

According to an aspect of the present disclosure, it is possible to improve an accuracy in transferring a line-and-space pattern from a reflective mask to a target substrate using EUV light.

### BRIEF DESCRIPTION OF THE DRAWINGS

Other objects and further features of the present disclosure will be apparent from the following detailed description when read in conjunction with the accompanying drawings, in which:

FIG. 1 is a cross-sectional view showing a reflective mask blank according to an embodiment;

FIG. 2 is a cross-sectional view showing a reflective mask according to the embodiment;

FIG. 3 is a cross-sectional view of the reflective mask for illustrating an example of EUV light reflected by the reflective mask of FIG. 2;

FIG. 4 is a diagram showing an example of the relationship among the chemical composition, the refractive index, and the extinction coefficient of the phase shift film;

FIG. 5 is a view showing an example of a light intensity distribution of a transferred image.

FIG. 6 is a flowchart showing a method of manufacturing a reflective mask blank according to the embodiment; and

FIG. 7 is a flowchart showing a method of manufacturing a reflective mask according to the embodiment.

### DESCRIPTION OF THE EMBODIMENT

In the following, embodiments of the present disclosure will be described with reference to the accompanying drawings. In each drawing, to the same or corresponding configurations, the same reference numeral will be assigned, and an explanation may be omitted. In the specification, a symbol “to” representing a numerical range indicates that values before and after the symbol are included as a lower limit value and an upper limit value, respectively.

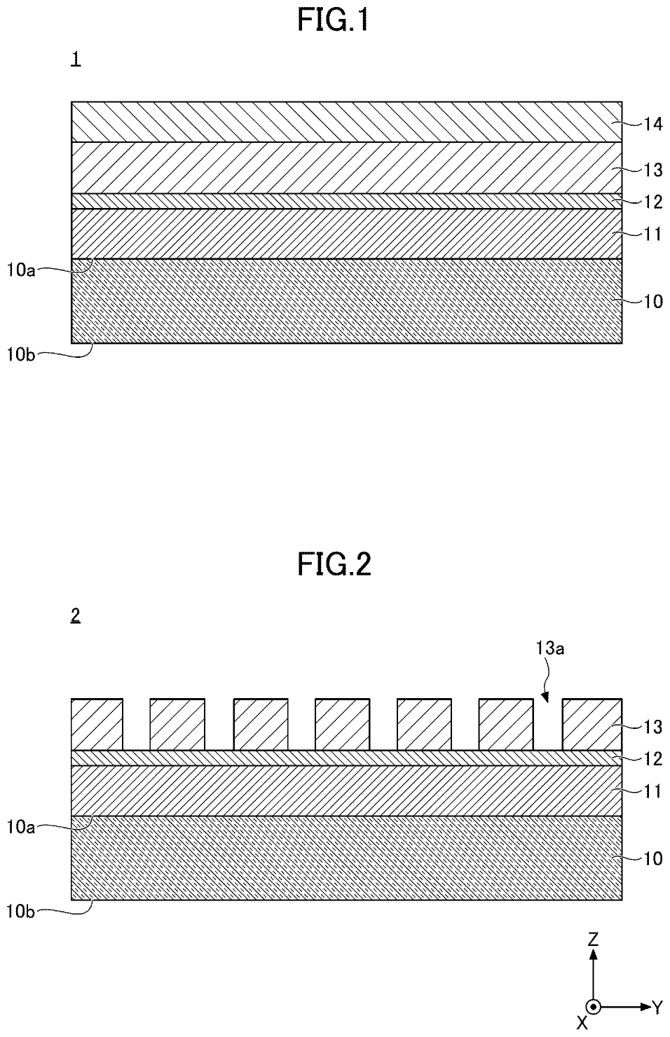

A reflective mask blank 1 according to an embodiment will be described with reference to FIG. 1. The reflective mask blank 1 includes, for example, the substrate 10; a multilayer reflective film 11; a protection film 12; a phase shift film 13; and an etching mask film 14, in this order. The multilayer reflective film 11, the protection film 12, the phase shift film 13, and the etching mask film 14 are formed in this order on the first main surface 10a of the substrate 10. The reflective mask blank 1 only needs to have at least the substrate 10, the multilayer reflective film 11, and the phase shift film 13.

The reflective mask blank 1 may further have a functional film, which is not shown. For example, the reflective mask blank 1 may have a conductive film on the side opposite to the multilayer reflective film 11 with respect to the substrate 10. The conductive film may be used, for example, to attract a reflective mask 2 to an electrostatic chuck of an exposure apparatus. The reflective mask blank 1 may have a diffusion barrier film (not shown) between the multilayer reflective film 11 and the protection film 12. The diffusion barrier film prevents metal elements contained in the protection film 12 from diffusing into the multilayer reflective film 11.

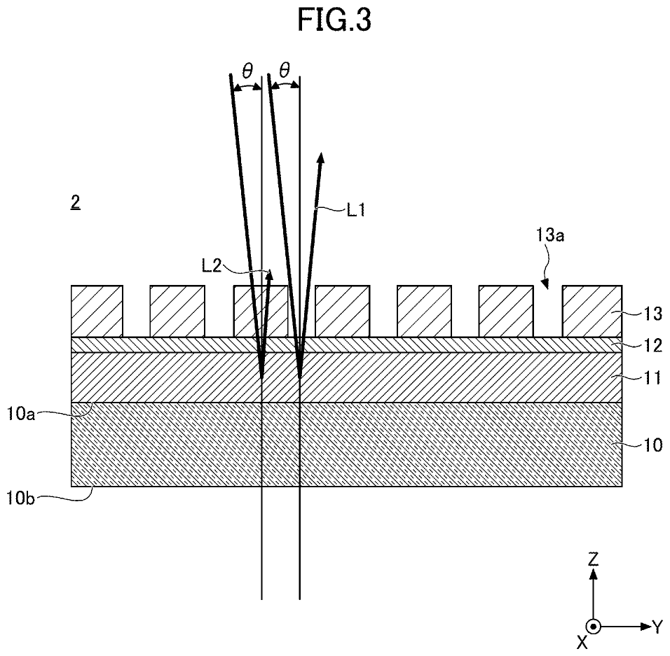

Next, the reflective mask 2 according to the embodiment will be described with reference to FIGS. 2 and 3. In FIGS. 2 and 3, an X-axis direction, a Y-axis direction, and a Z-axis direction are directions orthogonal to each other. The Z-axis direction is a direction perpendicular to a first main surface 10a of a substrate 10. The X-axis direction is the longitudinal direction of lines of the line-and-space pattern. The Y-axis direction is the width direction of the lines.

The reflective mask 2 is manufactured using, for example, the reflective mask blank 1 shown in FIG. 1, and includes the opening pattern 13a in the phase shift film 13. The opening pattern 13a includes a line-and-space pattern. The etching mask film 14 shown in FIG. 1 is removed after the opening pattern 13a is formed in the phase shift film 13.

In EUVL, the opening pattern 13a of the phase shift film 13 is transferred to a target substrate, such as a semi-conductor substrate. The transferring includes transferring a reduced opening pattern. In the following, the substrate 10, the multilayer reflective film 11, the protection film 12, the phase shift film 13, and the etching mask film 14 will be described in this order.

The substrate 10 is, for example, a glass substrate. A material of the substrate 10 is preferably quartz glass containing TiO₂. Compared with general soda lime glass, a linear expansion coefficient of the quartz glass is small, and thereby a dimensional change due to a temperature change is small. The quartz glass may contain 80 mass % to 95 mass % of SiO₂ and 4 mass % to 17 mass % of TiO₂. When the TiO₂ content is 4 mass % to 17 mass %, the linear expansion coefficient around room temperature is substantially zero, and almost no dimensional change around room temperature occurs. The quartz glass may contain a third component or impurity other than SiO₂ and TiO₂. The material of the substrate 10 may be crystallized glass in which a β-quartz solid solution is precipitated, silicon, metal, or the like.

The substrate 10 has the first main surface 10a and a second main surface 10b opposite to the first main surface 10a. The multilayer reflective film 11 and the like are formed on the first main surface 10a. The size of the substrate in a plan view (viewed in the Z-axis direction) is, for example, 152 mm longitudinally and 152 mm laterally. The longitudinal and lateral dimensions may be greater than or equal to 152 mm. Each of the first main surface 10a and the second main surface 10b has, for example, a square-shaped quality-guaranteed region at the center thereof. The size of the quality-guaranteed region is, for example, 142 mm longitudinally and 142 mm laterally. The quality-guaranteed region on the first main surface 10a preferably has a root mean square (RMS) roughness of 0.15 nm or less and a flatness of 100 nm or less. The quality-guaranteed region of the first main surface 10a is preferably free from a defect that may cause a phase defect.

The multilayer reflective film 11 reflects EUV light. The multilayer reflective film 11 is formed by alternately stacking, for example, a high refractive index layer and a low refractive index layer. A material of the high refractive index layer is, for example, silicon (Si), and a material of the low refractive index layer is, for example, molybdenum (Mo). With this combination, the multilayer reflective film is a Mo/Si multilayer reflective film. In addition, a Ru/Si multilayer reflective film, a Mo/Be multilayer reflective film, a Mo compound/Si compound multilayer reflective film, a Si/Mo/Ru multilayer reflective film, a Si/Mo/Ru/Mo multilayer reflective film, a Si/Ru/Mo/Ru multilayer reflective film, or the like can also be used as the multilayer reflective film 11.

The film thickness of each layer constituting the multilayer reflective film 11 and the number of repeating units of layers can be appropriately selected according to the material of each layer and a reflectance to EUV light. When the multilayer reflective film 11 is a Mo/Si multilayer reflective film, in order to achieve a reflectance of 60% or more with respect to EUV light having an incident angle θ (see FIG. 3) of 6°, a Mo layer having a film thickness of 2.3±0.1 nm and a Si layer having a film thickness of 4.5±0.1 nm may be stacked so that the number of repeating units is 30 or more and 60 or less. The multilayer reflective film 11 preferably has the reflectance of 60% or more to EUV light at an incident angle θ of 6°. The reflectance is more preferably 65% or more.

The method of forming each layer constituting the multilayer reflective film 11 is, for example, a DC sputtering method, a magnetron sputtering method, or an ion beam sputtering method. For example, film formation conditions for each of the Mo layer and the Si layer, when a Mo/Si multilayer reflective film is formed by the ion beam sputtering method, are as follows.

### <Film Formation Conditions for Si Layer>

Target: Si;

Sputtering gas: Ar;

Gas pressure: 1.3×10⁻² Pa to 2.7×10⁻² Pa;

Ion acceleration voltage: 300 V to 1500 V;

Film formation rate: 0.030 nm/sec to 0.300 nm/sec; and

Film thickness of Si layer: 4.5±0.1 nm.

### <Film Formation Conditions for Mo Layer>

Target: Mo;

Sputtering gas: Ar;

Gas pressure: 1.3×10⁻² Pa to 2.7×10⁻² Pa;

Ion acceleration voltage: 300 V to 1500 V;

Film formation rate: 0.030 nm/sec to 0.300 nm/sec; and

Film thickness of Mo layer: 2.3±0.1 nm

### <Repeating Unit of Si Layer and Mo Layer>

Number of repeating units: 30 to 60 (preferably 40 to 50).

The protection film 12 is formed between the multilayer reflective film 11 and the phase shift film 13 to protect the multilayer reflective film 11 from the etching gas. The etching gas is used to form an opening pattern 13a (see FIG. 2) in the phase shift film 13. The etching gas is, for example, a halogen-based gas, an oxygen-based gas, or a mixed gas thereof. Details of the etching gas will be described later. The protection film 12 is not removed even when exposed to the etching gas, and remains on the multilayer reflective film 11.

The protection film 12 has resistance to sulfuric acid-hydrogen peroxide mixture (SPM), which is a cleaning liquid, and protects the multilayer reflective film 11 from the sulfuric acid-hydrogen peroxide mixture. The sulfuric acid-hydrogen peroxide mixture is used, for example, to remove a resist film (not shown) or to clean the reflective mask 2. The resist film is formed on the etching mask film 14 (or the phase shift film 13 when the etching mask film 14 is not present).

The protection film 12 contains, for example, at least one element selected from ruthenium (Ru), rhodium (Rh), and silicon (Si). When the protection film 12 contains rhodium, the protection film 12 may contain only rhodium, or may further contain an element selected from the group consisting of nitrogen (N), oxygen (O), carbon (C), boron (B), ruthenium (Ru), niobium (Nb), molybdenum (Mo), tantalum (Ta), iridium (Ir), palladium (Pd), zirconium (Zr), yttrium (Y), and titanium (Ti), in addition to rhodium.

The material of the protection film 12 may be a rhodium alloy. The rhodium alloy contains at least one element X selected from the group consisting of Ru, Nb, Mo, Ta, Ir, Pd, Zr, Ti, and Y, in addition to Rh. In the case where the element X is Ru, Nb, Mo, Zr, Ti, or Y, the extinction coefficient k can be reduced without greatly increasing the refractive index n, thereby improving the reflectance with respect to EUV light. When the element X is Ru, Ta, Ir, Pd, or Y, the etching durability against a specific gas and the durability against cleaning can be improved. The element X is preferably Ru, Nb, Mo, Y, or Zr.

An element ratio of X to Rh (X:Rh) is preferably 1:99 to 1:1. In the present specification, the element ratio means a molar ratio. When the ratio (X/Rh) is 1/99 or more, the reflectance with respect to EUV light is good. When the ratio (X/Rh) is less than or equal to 1, the durability of the protection film 12 against the etching gas is good. The element ratio of X to Rh (X:Rh) is more preferably 3:10 to 1:1.

The protection film 12 may contain, in addition to Rh, at least one element Z selected from the group consisting of N, O, C, and B. Although the element Z reduces the resistance of the protection film 12 to the etching gas, the element Z prevents the protection film 12 from being crystallized, and thus can enhance the smoothness of the protection film 12. The protection film 12 containing the element Z has a non-crystalline structure or a microcrystalline structure. When the protection film 12 has a non-crystalline structure or a microcrystalline structure, the X-ray diffraction profile of the protection film 12 does not exhibit a clear peak.

When the protection film 12 contains Z in addition to Rh, it is preferable that the content of Rh or the total content of Rh and X is 40 at % to 99 at %, and the total content of Z is 1 at % to 60 at %. When the protection film 12 contains Z in addition to Rh, the content of Rh or the total content of Rh and X is more preferably from 80 at % to 99 at %, and the total content of Z is more preferably from 1 at % to 20 at %.

When the protection film 12 contains 90 at % or more of Rh, contains at least one element selected from the group consisting of X and Z, and has a film density of 10.0 g/cm 3 to 14.0 g/cm 3, the protection film 12 has a non-crystalline structure or a microcrystalline structure. The film density of the protection film 12 is preferably 11.0 g/cm 3 to 13.0 g/cm 3. When the protection film 12 contains 100 at % of Rh and has a film density of 11.0 g/cm 3 to 12.0 g/cm 3, the protection film 12 has a non-crystalline structure or a microcrystalline structure. The film density of the protection film 12 is measured using an X-ray reflectance method.

The thickness of the protection film 12 is preferably 1.0 nm or more and 10.0 nm or less, and more preferably 2.0 nm or more and 3.5 nm or less.

The root-mean-square (RMS) roughness of the protection film 12 is preferably 0.3 nm or less, and more preferably 0.1 nm or less.

The method of forming the protection film 12 includes, for example, a DC sputtering method, a magnetron sputtering method, or an ion beam sputtering method. For example, film formation conditions, when a Rh film is formed by the DC sputtering method, are as follows.

### <Film Formation Conditions for Rh Film>

Target: Rh;

Sputtering gas: Ar;

Gas pressure: 1.0×10⁻² Pa to 1.0×10⁰ Pa;

Input power density per unit target area: 1.0 W/cm² to 8.5 W/cm²;

Film formation rate: 0.020 nm/sec to 1.000 nm/sec; and

Film thickness of Rh film: 1 nm to 10 nm.

When the Rh film is formed, a N₂ gas or a mixture gas of an Ar gas and a N₂ gas may be used as the sputtering gas. The volume ratio of a N₂ gas in the sputtering gas, N₂/(Ar+N₂), is 0.05 or more and 1.0 or less.

For example, film formation conditions, when a RhO film is formed by the DC sputtering method, are as follows.

### <Film Formation Conditions for RhO Film>

Target: Rh;

Sputtering gas: an O₂ gas, or a mixture gas of an Ar gas and an O₂ gas;

Volume ratio of an O₂ gas in sputtering gas (O₂/(Ar+O₂)): 0.05 to 1.0;

Gas pressure: 1.0×10⁻² Pa to 1.0×10⁰ Pa;

Input power density per unit target area: 1.0 W/cm² to 8.5 W/cm²;

Film formation rate: 0.020 nm/sec to 1.000 nm/sec; and

Film thickness of RhO film: 1 nm to 10 nm.

For example, film formation conditions, when a RhRu film is formed by the DC sputtering method, are as follows.

### <Film Formation Conditions for RhRu Film>

Target: Rh and Ru (or RhRu);

Sputtering gas: Ar;

Gas pressure: 1.0×10⁻² Pa to 1.0×10⁰ Pa;

Input power density per unit target area: 1.0 W/cm² to 8.5 W/cm²;

Film formation rate: 0.020 nm/sec to 1.000 nm/sec; and

Film thickness of RhRu film: 1 nm to 10 nm.

The phase shift film 13 is a film in which the opening pattern 13a is to be formed. The opening pattern 13a is not formed in the manufacturing process of the reflective mask blank 1 but is formed in the manufacturing process of the reflective mask 2. The phase shift film 13 shifts a phase of second EUV light L2 with respect to a phase of first EUV light L1 shown in FIG. 3. The first EUV light L1 is light that entered and passed through the opening pattern 13a without passing through the phase shift film 13, was reflected by the multilayer reflective film 11, and passed through the opening pattern 13a again without passing through the phase shift film 13 and exited. The second EUV light L2 is light that entered and passed through the phase shift film 13 while being absorbed by the phase shift film 13, was reflected by the multilayer reflective film 11, and passed through the phase shift film 13 while being absorbed again by the phase shift film 13 and exited. The phase difference between the first EUV light L1 and the second EUV light L2 is, for example, 170° to 250°. A phase of the first EUV light L1 may be advanced or retarded from a phase of the second EUV light L2. The phase difference between the first EUV light L1 and the second EUV light L2 is preferably 180° to 245°, more preferably 190° to 240°, and even more preferably 190° to 235°. The phase shift film 13 improves a contrast of a transferred image by utilizing an interference between the first EUV light L1 and the second EUV light L2. The transferred image is an image obtained by transferring the opening pattern 13a of the phase shift film 13 to a target substrate.

Conventionally, chemical compositions and structures of the phase shift film 13 for EUVL have been studied. However, in the case where the opening pattern 13a includes a line-and-space pattern, sufficient studies have not been performed.

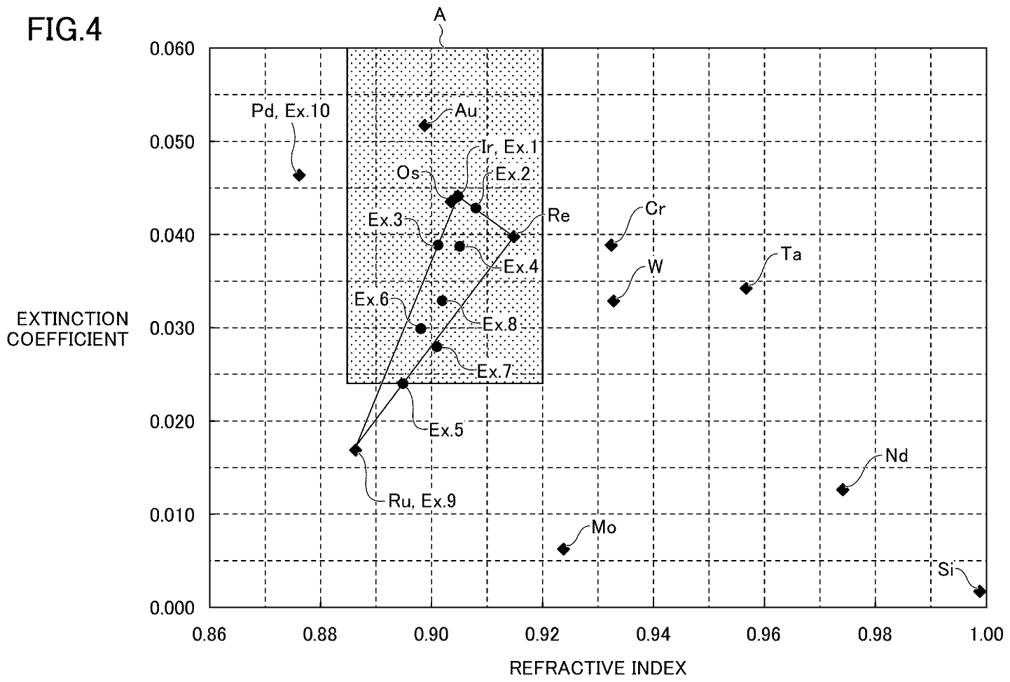

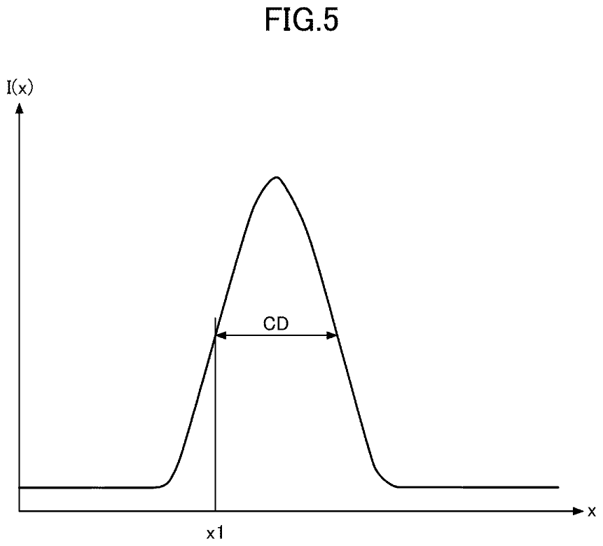

The inventors of the present application focused on the refractive index n of the phase shift film 13 with respect to EUV light and the extinction coefficient k of the phase shift film 13 with respect to EUV light. FIG. 4 shows the refractive index and the extinction coefficient of each element that can be contained in the phase shift film 13. As will be explained in detail in the description of Examples, the inventors of the present application have found that there is a range in which the accuracy in transferring the line-and-space pattern can be improved (for example, a range A shown in FIG. 4) in a part of a range in which the refractive index n is 0.920 or less and the extinction coefficient k is 0.024 or more.

For the optical properties (refractive index n and extinction coefficient k) of the phase shift film 13, values in the database of the Center for X-Ray Optics, Lawrence Berkeley National Laboratory, or values calculated from a formula of “incident angle dependence” of reflectance, which will be described later, will be used.

The incident angle θ of the EUV light, the reflectance R for the EUV light, the refractive index n of the phase shift film 13, and the extinction coefficient k of the phase shift film 13 satisfy the following equation (1),

$$\begin{matrix}[ Math 1 ] & \\ R = \vert \frac{sin θ - {( {( n + ik )}^{2} - {cos}^{2} θ )}^{1 / 2}}{sin θ + {( {( n + ik )}^{2} - {cos}^{2} θ )}^{1 / 2}} \vert . & ( 1 )\end{matrix}$$

Measurements are made for the combination of the incident angle θ and the reflectance R a plurality of times, and the refractive index n and extinction coefficient k are estimated by the least squares method so that errors between the plural measurement data and the values of the equation (1) are minimized.

The phase shift film 13 has a refractive index n of 0.920 or less, an extinction coefficient k of 0.024 or more, a thickness t of 50 nm or less, a normalized image log slope NILS of a transferred image of 2.90 or more, and a tolerance range m of a focal depth of the transferred image of 60 nm or less. The transferred image is obtained by transferring the line-and-space pattern included in the opening pattern 13a to the target substrate.

The normalized image log slope NILS of the transferred image is a value expressing a contrast of the transferred image, and is calculated using the following equation (2).

$$\begin{matrix}[ Math 2 ] & \\ NILS = CD \times \frac{\partial ln I ( x )}{\partial x} , & ( 2 )\end{matrix}$$

where I(x) is a light intensity of the transferred image (an intensity normalized by the maximum intensity (dimensionless quantity)), x represents a location in the width direction (direction orthogonal to the line, which corresponds to the Y-axis direction in FIG. 3) of the transferred image (unit: nm), and CD represents a critical dimension of the transferred image.

I(x) is determined by lithography simulation based on optical imaging theory. The simulation based on the optical imaging theory is performed based on, for example, a publicly-known document (“Lithography Optics”, Koichi MATSUMOTO, Japanese journal of optics: publication of the Optical Society of Japan 30(3), 194-201, March 2001).

### <Simulation Conditions>

Wavelengths of EUV light: 13.5 nm;

Incident angle θ: 6°;

Number of aperture NA of EUV exposure apparatus: 0.33;

Opening pattern of phase shift film: line-and-space;

Reduction magnification of pattern transferred image: 4;

Line pitch p of transferred image: 26 nm, 28 nm, 32 nm, and 36 nm;

Duty ratio of transferred image (ratio of width of line to width of space): 1:1;

Critical Dimension CD of transferred image: 13 nm, 14 nm, 16 nm, and 18 nm; and

Illumination system of EUV exposure apparatus: dipole illumination (σ=0.7/0.5).

In order to reflect a projection effect to be described later on I(x), as shown in FIG. 3, the optical axis of the EUV light is inclined toward the Y-axis direction on propagating in the Z-axis direction. As shown in FIG. 3, the incident light beam is inclined toward the Y-axis positive direction on propagating in the Z-axis negative direction, and the reflected light beam is inclined toward the Y-axis positive direction on propagating in the Z-axis positive direction. When viewed in the X-axis direction, the optical axis of the EUV light is inclined. However, when viewed in the Y-axis direction, the optical axis of the EUV light is vertical. The X-axis direction is orthogonal to an incident plane of the EUV light (plane including the incident light beam and the reflected light beam).

In the simulation, although the calculation in the ZY plane is exemplified above, the calculation may be performed for the incident light inclined with respect to the ZX plane in FIG. 3 in addition to the above. In this case, eight types of I(x) are obtained.

As shown in FIG. 5, the normalized image log slope NILS of the transferred image is obtained by calculating the slope of ln I(x) (natural logarithm of I(x)) at x (x=x1) where the peak width of I(x) is equal to the CD, and multiplying the calculated slope by the CD. The larger the NILS, the higher the contrast of the transferred image. The NILS where the line pitch of the transferred image is 32 nm and the critical dimension (CD) of the transferred image is 16 nm is, for example, 2.9 or more, and preferably 3.0 or more. The upper limit of the NILS is not particularly limited, but is preferably 4.5 or less, and more preferably 3.5 or less. I(x) is a value at the best focus position which will be described later.

The tolerance range m of the focal depth of the transferred image is a difference between the maximum value and the minimum value at the best focus position when the line pitch p of the transferred image is 26 nm, 28 nm, 32 nm, and 36 nm. The best focus position is a focal position of the EUV exposure apparatus at which I(x) takes the maximum value at x=x1. As the tolerance range m is smaller, it is easier to simultaneously focus on a plurality of line pitches p. The upper limit of the tolerance range m is preferably 60 nm or less, and more preferably 55 nm or less. The lower limit of the tolerance range m is not particularly limited, but the tolerance range m is 0 nm or more, and preferably 5 nm or more.

The smaller the refractive index n of the phase shift film 13 is, the larger the normalized image log slope NILS is even if the film thickness t of the phase shift film 13 is small. The refractive index n is, for example, 0.920 or less, preferably 0.910 or less, and more preferably 0.900 or less. The refractive index n is preferably 0.880 or more, and more preferably 0.885 or more.

As the extinction coefficient k of the phase shift film 13 increases, the tolerance range m of the depth of focus becomes smaller and the normalized image log slope NILS can be improved. On the other hand, when the extinction coefficient k is too large, the normalized image log slope NILS in a line-and-space pattern having a large pitch decreases. The extinction coefficient k is, for example, 0.024 or more, preferably 0.030 or more, more preferably 0.035 or more, and still more preferably 0.040 or more. The extinction coefficient k is preferably 0.065 or less, more preferably 0.060 or less, still more preferably 0.055 or less, and particularly preferably 0.050 or less.

As the film thickness t of the phase shift film 13 is smaller, the projection effect (shadowing effect) is reduced. The shadowing effect is, for example, as shown in FIG. 3, caused by an incident angle θ of EUV light that is not 0° (e.g. 6°), which causes occurrence of a region near the opening edge of the opening pattern 13a that blocks the EUV light by the phase shift film 13, resulting in a dimensional displacement of the transferred image from the desired dimension.

The smaller the thickness t of the phase shift film 13 is, the better the processing accuracy of the opening pattern 13a is.

The thickness t of the phase shift film is, for example, 50 nm or less, preferably 45 nm or less, and more preferably 35 nm or less. The thickness t is preferably 15 nm or more, and more preferably 20 nm or more.

The reflectance of the phase shift film 13 is preferably 12% or less, more preferably 11% or less, and still more preferably 10% or less. The lower limit of the reflectance of the phase shift film 13 is not particularly limited, but is preferably 1.2% or more, and more preferably 2.0% or more. Here, the reflectance of the phase shift film 13 is a relative reflectance of second EUV light L2 with respect to first EUV light L1 shown in FIG. 3 (i.e., a reflectance of the second EUV light when the reflectance of the first EUV light L1 is 100%).

The phase shift film 13 contains, for example, at least one element selected from the first group consisting of iridium (Ir), platinum (Pt), gold (Au), silver (Ag), osmium (Os), and rhenium (Re). Ir, Pt, Au, Os, and Re can improve a rate of etching the phase shift film 13. In addition, Ir and Pt can improve resistance to a sulfuric acid-hydrogen peroxide mixture.

The phase shift film 13 may contain at least one element selected from the second group consisting of ruthenium (Ru), silicon (Si), tantalum (Ta), niobium (Nb), tungsten (W), and chromium (Cr) in addition to the one element selected from the first group. Ru, Si, Ta, Nb, W and Cr can improve the rate of etching the phase shift film 13. In addition, Ru, Si, and Ta can improve the resistance to a sulfuric acid-hydrogen peroxide mixture.

The phase shift film 13 may be a film of a single layer or may be a film composed of a plurality of layers (laminated film). The single layer film is composed of a single metal or an alloy. The alloy may contain, for example, two or more elements selected from the first group, two or more elements selected from the second group, or one or more elements selected from the first group and one or more elements selected from the second group. The laminated film includes at least a first layer and a second layer having a chemical composition different from that of the first layer. Each of the first layer and the second layer is formed of a single metal or an alloy. The laminated film may include the first layer and the second layer repeatedly.

When the phase shift film 13 includes the first layer and the second layer, the refractive index n of the phase shift film 13 is calculated from the following formula (3).

$$\begin{matrix}[ Math 3 ] & \\ n = {n}_{1} \cdot \frac{{t}_{1} \cdot \frac{{d}_{1}}{{M}_{1}}}{{t}_{1} \cdot \frac{{d}_{1}}{{M}_{1}} + {t}_{2} \cdot \frac{{d}_{2}}{{M}_{2}}} + {n}_{2} \cdot \frac{{t}_{2} \cdot \frac{{d}_{2}}{{M}_{2}}}{{t}_{1} \cdot \frac{{d}_{1}}{{M}_{1}} + {t}_{2} \cdot \frac{{d}_{2}}{{M}_{2}}} & ( 3 )\end{matrix}$$

where n₁ is the refractive index of the first layer, n₂ is the refractive index of the second layer, t₁ is the thickness of the first layer, t₂ is the thickness of the second layer, d₁ is the density of the first layer, d₂ is the density of the second layer, M₁ is the atomic mass of the first layer, and M₂ is the atomic mass of the second layer.

When the phase shift film 13 includes the first layer and the second layer, the extinction coefficient k of the phase shift film 13 is calculated from the following formula (4).

$$\begin{matrix}[ Math 4 ] & \\ k = {k}_{1} \cdot \frac{{t}_{1} \cdot \frac{{d}_{1}}{{M}_{1}}}{{t}_{1} \cdot \frac{{d}_{1}}{{M}_{1}} + {t}_{2} \cdot \frac{{d}_{2}}{{M}_{2}}} + {k}_{2} \cdot \frac{{t}_{2} \cdot \frac{{d}_{2}}{{M}_{2}}}{{t}_{1} \cdot \frac{{d}_{1}}{{M}_{1}} + {t}_{2} \cdot \frac{{d}_{2}}{{M}_{2}}} & ( 4 )\end{matrix}$$

where k₁ is the extinction coefficient of the first layer, k₂ is the extinction coefficient of the second layer, t₁ is the thickness of the first layer, t₂ is the thickness of the second layer, d₁ is the density of the first layer, d₂ is the density of the second layer, M₁ is the atomic mass of the first layer, and M₂ is the atomic mass of the second layer.

The phase shift film 13 may include, in addition to the first layer and the second layer, a third layer having a chemical composition different from that of the first layer and the second layer. Also in the case where the third layer is included, the refractive index n and the extinction coefficient k can be calculated using formulas similar to the above formulas (3) and (4).

The phase shift film 13 contains, for example, Ir, or contains Ir and Re. In the case of containing Ir and Re, the element ratio of Re to Ir (Re:Ir) is preferably 0:1 to 1:1. The phase shift film 13 may contain only Ir, but preferably contains Re in addition to Ir. Re can improve the rate of etching the phase shift film 13 without impairing the optical characteristics (refractive index n and extinction coefficient k) of the phase shift film 13. When the ratio (Re/Ir) is 1 or less, the resistance of the phase shift film 13 to the sulfuric acid-hydrogen peroxide mixture is good. The element ratio of Re to Ir (Re:Ir) is preferably 1:9 to 5:5, and more preferably 2:8 to 4:6.

The phase shift film 13 may contain Ir or may contain Ir and Ru. In the case of containing Ir and Ru, the element ratio of Ru to Ir (Ru:Ir) is preferably 0:1 to 1:1. The phase shift film 13 may contain only Ir, but preferably contains Ru in addition to Ir. Ru can reduce the refractive index n of the phase shift film 13, reduce the film thickness t of the phase shift film 13, and increase the NILS. When the ratio (Ru/Ir) is 1 or less, a decrease in the extinction coefficient k of the phase shift film 13 can be suppressed, and an excessive increase in the tolerance range m of the depth of focus can be suppressed. The element ratio of Ru to Ir (Ru:Ir) is preferably 1:9 to 5:5, and more preferably 2:8 to 4:6.

The phase shift film 13 may contain Ir, Re, and Ru. In this case, the element ratio of Re to Ir (Re:Ir) is preferably 1:99 to 80:20, and the element ratio of Ru to Ir (Ru:Ir) is preferably 1:99 to 80:20. The element ratio of Re to Ir (Re:Ir) is more preferably 1:9 to 5:5, and still more preferably 2:8 to 3:7. The element ratio of Ru to Ir (Ru:Ir) is more preferably 1:9 to 4:6, and still more preferably 1:9 to 2:8.

When the phase shift film 13 contains Re and Ru, the phase shift film 13 may further contain Ir or may not contain Ir. The element ratio of Ru to Re (Ru:Re) is preferably 3:7 to 7:3. When Ru is added to Re, the resistance to sulfuric acid-hydrogen peroxide mixture is improved, but the extinction coefficient k decreases. When the ratio (Ru/Re) is 3/7 or more, the resistance of the phase shift film 13 to the sulfuric acid-hydrogen peroxide mixture is good. When the ratio (Ru/Re) is 7/3 or less, a decrease in the extinction coefficient k of the phase shift film 13 can be suppressed, and an excessive increase in the tolerance range m of the depth of focus can be suppressed. The element ratio of Ru to Re (Ru:Re) is more preferably 5:5 to 6:4.

As described above, the etching gas is used to form the opening pattern 13a of the phase shift film 13. The etching gas is, for example, a halogen-based gas, an oxygen-based gas, or a mixed gas thereof.

Examples of the halogen-based gas include a chlorine-based gas and a fluorine-based gas. The chlorine-based gas is, for example, a Cl₂ gas, a SiCl₄ gas, a CHCl₃ gas, a CCl₄ gas, a BCl₃ gas, or a mixture of thereof. The fluorine-based gas is, for example, a CF₄ gas, a CHF₃ gas, a SF₆ gas, a BF₃ gas, a XeF₂ gas, or a mixture of thereof. The oxygen-based gas is an O₂ gas, an O₃ gas, or a mixture thereof.

When the phase shift film 13 contains Ir, a fluorine-based gas is preferable as the halogen-based gas. The fluorine-based gas is preferably used as a mixed gas with the oxygen-based gas rather than being used alone. The volume ratio of the oxygen-based gas to the fluorine-based gas (oxygen-based gas:fluorine-based gas) is preferably 10:90 to 50:50, and more preferably 20:80 to 40:60.

A ratio of the rate of etching the phase shift film 13 using the etching gas to the rate of etching the protection film 12 using the etching gas is also referred to as a selection ratio. The selection ratio is preferably 5 or more. The larger the selection ratio, the better the etching resistance of the protection film 12. The selection ratio is preferably 200 or less, and more preferably 100 or less.

The rate of etching the phase shift film 13 with the sulfuric acid-hydrogen peroxide mixture is 0 nm/min to 0.05 nm/min. The sulfuric acid-hydrogen peroxide mixture is used for removing the resist film, cleaning the reflective mask 2, or the like. When the rate of etching the phase shift film 13 with the sulfuric acid-hydrogen peroxide mixture is 0.05 nm/min, damage to the phase shift film 13 during cleaning can be suppressed.

The method of forming the phase shift film 13 is, for example, a DC sputtering method, a magnetron sputtering method, or an ion beam sputtering method.

The etching mask film 14 is formed on the phase shift film 13 and is used to form an opening pattern 13a in the phase shift film 13. A resist film (not shown) is provided on the etching mask film 14. In the manufacturing process of the reflective mask 2, a first opening pattern is first formed in a resist film, a second opening pattern is then formed in the etching mask film 14 using the first opening pattern, and a third opening pattern 13a is then formed in the phase shift film 13 using the second opening pattern. The first opening pattern, the second opening pattern, and the third opening pattern 13a have the same dimensions and the same shape in a plan view (when viewed in the Z-axis direction). The etching mask film 14 enables the resist film to be thinned.

The etching mask film 14 contains at least one element selected from the group consisting of Ru, Al, Hf, Y, Cr, Nb, Ti, Mo, Ta, and Si. The etching mask film 14 may contain at least one element selected from the group consisting of O, N, C, and B, in addition to the elements described above. The etching mask film 14 preferably contains at least one element selected from the group consisting of O, N, and B, and more preferably contains at least one element selected from the group consisting of O and N.

The thickness of the etching mask film 14 is preferably 2 nm or more and 30 nm or less, more preferably 2 nm or more and 25 nm or less, and further preferably 2 nm or more and 10 nm or less.

The method of forming the etching mask film 14 is, for example, a DC sputtering method, a magnetron sputtering method, or an ion beam sputtering method.

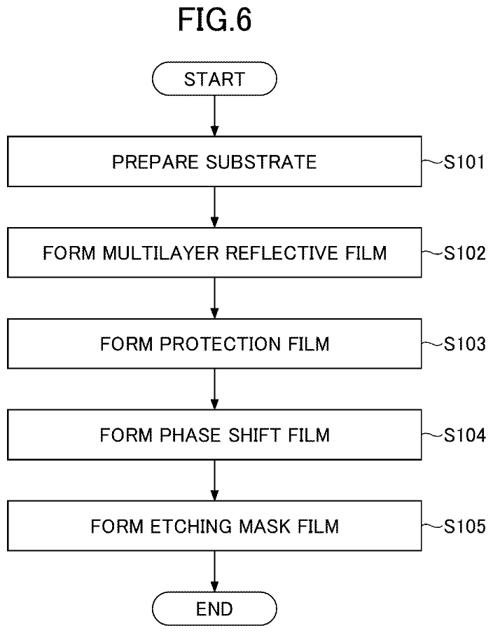

Next, a method of manufacturing a reflective mask blank 1 according to one embodiment of the present disclosure will be described with reference to FIG. 6. The method of manufacturing the reflective mask blank 1 includes, for example, steps S101 to S105 shown in FIG. 6. A substrate 10 is prepared (step S101). A multilayer reflective film 11 is formed on a first main surface 10a of the substrate 10 (step S102). A protection film 12 is formed on the multilayer reflective film 11 (step S103). A phase shift film 13 is formed on the protection film 12 (step S104). An etching mask film 14 is formed on the phase shift film 13 (step S105). It is sufficient as long as the method of manufacturing the reflective mask blank 1 includes at least steps S101, S102, and S104. The method of manufacturing the reflective mask blank 1 may further include a step of forming a functional film (not shown).

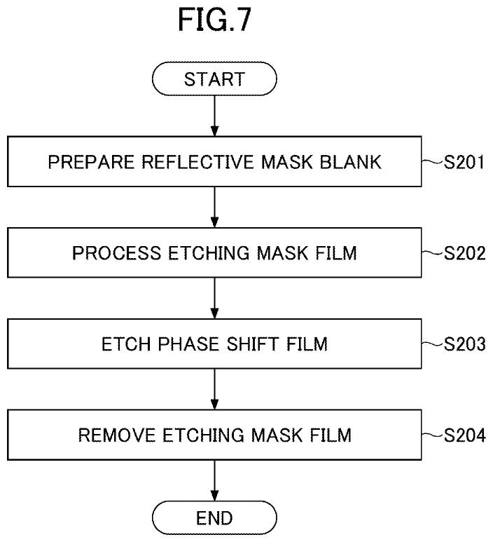

Next, a method of manufacturing a reflective mask 2 according to the embodiment of the present disclosure will be described with reference to FIG. 7. The method of manufacturing the reflective mask 2 includes steps S201 to S204 shown in FIG. 7. A reflective mask blank 1 is prepared (step S201). An etching mask film 14 is processed (step S202). A resist film (not shown) is provided on the etching mask film 14. First, a first opening pattern is formed in a resist film, and then a second opening pattern is formed in the etching mask film 14 by using the first opening pattern. A third opening pattern 13a is formed in a phase shift film 13 using the second opening pattern (step S203). In step S203, the phase shift film 13 is etched using an etching gas. The resist film and the etching mask film 14 are removed (step S204). For removing the resist film, for example, a sulfuric acid-hydrogen peroxide mixture is used. For example, an etching gas is used to remove the etching mask film 14. The etching gas used in step S204 (removal of the etching mask film 14) may be the same type as the etching gas used in step S203 (formation of the opening pattern 13a). It is sufficient as long as the method of manufacturing the reflective mask 2 includes at least steps S201 and S203.

### EXAMPLES

Hereinafter, experimental data will be described. Examples 1 to 8 and 10 below are practical examples, and Examples 9 and 11 below are comparative examples.

In Example 1, an EUV mask blank including a substrate, a multilayer reflective film, a protection film, and a phase shift film was produced.

A SiO₂/TiO₂ glass substrate (outer shape: square having a size of 6 inches (152 mm) and a thickness of 6.3 mm) was prepared as a substrate. The glass substrate had a thermal coefficient of expansion at 20° C. of 0.02×10⁻⁷/° C., a Young modulus of 67 GPa, a Poisson ratio of 0.17, and a specific rigidity of 3.07×10⁷ m²/s². A quality-guaranteed region of the first main surface of the substrate had a root mean square (RMS) roughness of less than or equal to 0.15 nm and a flatness of less than or equal to 100 nm due to polishing. A Cr film having a thickness of 100 nm was formed on the second main surface of the substrate by a magnetron sputtering method. The sheet resistance of the Cr film was 100 Ω/□.

As the multilayer reflective film, a Mo/Si multilayer reflective film was formed. The Mo/Si multilayer reflective film was formed by repeating times the formation of a Si layer (thickness was 4.5 nm) and a Mo layer (thickness was 2.3 nm) by an ion beam sputtering method. The total thickness of the Mo/Si multilayer reflective film was 272 nm ((4.5 nm+2.3 nm)×40).

A Rh film (thickness was 2.5 nm) was formed as the protection film. The Rh film was formed using a DC sputtering method. The reflectance of the EUV light by the multilayer reflective film after the protection film was formed, that is, the reflectance of the first EUV light L1 shown in FIG. 3, was 64.5% at the maximum.

In Example 1, an Ir film (thickness was 32 nm and Ir content was 100 at %) was formed as the phase shift film. The Ir film was formed using a DC sputtering method. The characteristics of the phase shift film are shown in TABLE 1.

In Examples 2 to 11, EUV mask blanks were produced under the same condition as in Example 1 except for the chemical composition and the film thickness of the phase shift film. The characteristics of the phase shift film are shown in TABLE 1. The phase shift film was an alloy film in Examples 2 to 8, and 11. The phase shift film was a single metal film in Examples 9 and 10.

TABLE 1

| | | | | Optical characteristics | | | EUVL characteristics | | | | | | Gas flow |
|---|---|---|---|---|---|---|---|---|---|---|---|---|---|
| | Composition | | | | Extinction | | Film | | Phase | Tolerance | | | rate |
| | (at %) | | | Refractive | coefficient | SPM | thickness | Reflectance | difference | range m | | ER | CF₄/O₂ |
| | Ir | Ru | Re | index n | k | resistance | t (nm) | (%) | (degrees) | (nm) | NILS | (nm/min) | (sccm) |
| Ex. 1 | 100 | 0 | 0 | 0.905 | 0.044 | YES | 32 | 7.3 | 180.9 | 45 | 2.9 | 11.19 | 24/8 |
| Ex. 2 | 70 | 0 | 30 | 0.908 | 0.043 | YES | 32 | 7.4 | 175.4 | 40 | 2.9 | 13.32 | 24/8 |
| Ex. 3 | 80 | 20 | 0 | 0.901 | 0.039 | YES | 33 | 6.6 | 193.2 | 45 | 2.9 | 8.66 | 24/8 |
| Ex. 4 | 56 | 14 | 30 | 0.905 | 0.039 | YES | 33 | 6.3 | 184.7 | 50 | 2.9 | 12.91 | 24/8 |
| Ex. 5 | 0 | 70 | 30 | 0.895 | 0.024 | YES | 42 | 9.5 | 244.8 | 30 | 2.9 | 35.06 | 4/28 |
| Ex. 6 | 30 | 49 | 21 | 0.898 | 0.030 | YES | 35 | 8.9 | 190.2 | 60 | 3.0 | 8.85 | 24/8 |
| Ex. 7 | 0 | 50 | 50 | 0.901 | 0.028 | YES | 41 | 8.1 | 232.1 | 25 | 2.9 | 41.01 | 4/28 |
| Ex. 8 | 30 | 35 | 35 | 0.902 | 0.033 | YES | 34 | 7.3 | 186.8 | 50 | 2.9 | 11.48 | 24/8 |
| Ex. 9 | 0 | 100 | 0 | 0.886 | 0.017 | YES | 30 | 39.7 | 179.9 | 95 | 2.4 | | |

| | | | | | | | | | |
|---|---|---|---|---|---|---|---|---|---|
| Ex. 10 | Pd | 0.876 | 0.046 | NO | 33 | 8.4 | 195.0 | 40 | 3.0 |
| Ex. 11 | TaSn | 0.955 | 0.055 | YES | 38 | 1.1 | 109.5 | | 2.8 |

In TABLE 1, the SPM resistance of the phase shift film and the etching rate (ER) of the phase shift film were measured under the following conditions.

For the evaluation of the SPM resistance of the phase shift film, the EUV mask blank was immersed in a sulfuric acid-hydrogen peroxide mixture at 100° C. for 20 minutes, and a change in film thickness of the phase shift film was measured by X-ray reflectometry (XRR). The SPM resistance was determined by the obtained rate of etching phase shift film in the sulfuric acid-hydrogen peroxide mixture. The sulfuric acid-hydrogen peroxide mixture was obtained by mixing concentrated sulfuric acid and hydrogen peroxide water in a ratio of 75 vol %:25 vol % (concentrated sulfuric acid:hydrogen peroxide water). The concentrated sulfuric acid contained 96 vol % of sulfuric acid and 4 vol % of water. The hydrogen peroxide water contained 30 vol % to 35 vol % of hydrogen peroxide and 65 vol % to 70 vol % of water. The SPM resistance of “YES” means that the rate of etching the phase shift film in the sulfuric acid-hydrogen peroxide mixture is 0.05 nm/min or less. The SPM resistance of “NO” means that the rate of etching the phase shift film in the sulfuric acid-hydrogen peroxide mixture is higher than 0.05 nm/min.

The etching rate ER of the phase shift film was determined by placing the EUV mask blank on a sample stage of an inductively coupled plasma (ICP) etching apparatus and performing ICP plasma etching under the following conditions.

### <Conditions for ICP Plasma Etching>

ICP antenna bias: 200 W;

Substrate bias: 40 W;

Trigger pressure: 3.5×10⁰ Pa;

Etching pressure: 3.0×10⁻¹ Pa;

Etching gas: mixture gas of O₂ and CF₄; and

Gas flow rate (CF₄/O₂): 24/8 sccm to 4/28 sccm.

In TABLE 1, the reflectance of the phase shift film is the relative reflectance of the second EUV light L2 with respect to the first EUV light L1 shown in FIG. 3 (the reflectance of the second EUV light L2 when the reflectance of the first EUV light L1 is taken as 100%).

As is clear from TABLE 1, according to Examples 1 to 8 and 10, the refractive index n of the phase shift film was 0.920 or less, the extinction coefficient k of the phase shift film was 0.024 or more, the thickness t of the phase shift film was 50 nm or less, the normalized image log slope NILS of the transferred image was 2.9 or more, and the tolerance range m of the focal depth of the transferred image was 60 nm or less. However, in Example 10, since a Pd film was used as the phase shift film, the SPM resistance was poor.

According to Comparative Example 9, the extinction coefficient k of the phase shift film was less than 0.024, the normalized image log slope NILS of the transferred image was less than 2.9, and the tolerance range m of the focal depth of the transferred image exceeded 60 nm.

In Comparative Example 11, the refractive index n of the phase shift film exceeded 0.920, and the normalized image log slope NILS of the transferred image was less than 2.9.

As described above, the reflective mask blank, the reflective mask, the method of manufacturing the reflective mask blank, and the method of manufacturing the reflective mask according to the present disclosure have been described. However, the present disclosure is not limited to the above-described embodiments, and the like. Various variations, modifications, substitutions, additions, deletions, and combinations are possible within the scope of claims. They also of course fall within the technical scope of the present disclosure.

What is claimed is:

1. A reflective mask blank comprising:
a substrate;
a multilayer reflective film that reflects EUV light;
a phase shift film that shifts a phase of the EUV light, the substrate, the multilayer reflective film, the phase shift film being arranged in this order, wherein
an opening pattern is to be formed in the phase shift film, and
the phase shift film has a refractive index of 0.920 or less with respect to the EUV light, an extinction coefficient of 0.024 or more with respect to the EUV light, a thickness of 50 nm or less, a normalized image log slope of 2.9 or more for a transferred image when a line-and-space pattern is formed on a target substrate, and a tolerance range of a focal depth of the transferred image is 60 nm or less.

2. The reflective mask blank according to claim 1, wherein
the phase shift film contains at least one element selected from the first group consisting of iridium (Ir), platinum (Pt), gold (Au), silver (Ag), osmium (Os), and rhenium (Re).

3. The reflective mask blank according to claim 1, wherein
the phase shift film contains at least one element selected from the first group consisting of iridium (Ir), platinum (Pt), gold (Au), osmium (Os), and rhenium (Re).

4. The reflective mask blank according to claim 2, wherein
the phase shift film contains at least one element selected from the second group consisting of ruthenium (Ru), silicon (Si), tantalum (Ta), niobium (Nb), tungsten (W), and chromium (Cr), in addition to the one element selected from the first group.

5. The reflective mask blank according to claim 2, wherein
the phase shift film contains Ir, or the phase shift film contains Ir and Re, and
when the phase shift film contains Ir and Re, an element ratio of Re to Ir (Re:Ir) is 0:1 to 1:1.

6. The reflective mask blank according to claim 2, wherein
the phase shift film contains Ir, or the phase shift film contains Ir and Ru, and
when the phase shift film contains Ir and Ru, an element ratio of Ru to Ir (Ru:Ir) is 0:1 to 1:1.

7. The reflective mask blank according to claim 2, wherein
the phase shift film contains Ir, Re, and Ru, and
an element ratio of Re to Ir (Re:Ir) is 1:99 to 80:20, and
an element ratio of Ru to Ir (Ru:Ir) is 1:99 to 80:20.

8. The reflective mask blank according to claim 2, wherein
the phase shift film contains Re and Ru, and
an element ratio of Ru to Re (Ru:Re) is 3:7 to 7:3.

9. The reflective mask blank according to claim 1, wherein
a rate of etching the phase shift film with a sulfuric acid-hydrogen peroxide mixture is 0 nm/min to 0.05 nm/min.

10. The reflective mask blank according to claim 1 further comprising:
a protection film formed between the multilayer reflective film and the phase shift film, the protection film protecting the multilayer reflective film from an etching gas used for forming the opening pattern in the phase shift film, wherein
a ratio of a rate of etching the phase shift film using the etching gas to a rate of etching the protection film using the etching gas is 5:1 or more.

11. The reflective mask blank according to claim 10, wherein
the protection film contains at least one element selected from ruthenium (Ru), rhodium (Rh), and silicon (Si).

12. The reflective mask blank according to claim 1, wherein
the phase shift film has a refractive index with respect to EUV light of 0.885 or more.

13. The reflective mask blank according to claim 1 further comprising:
an etching mask film on the phase shift film, wherein
the etching mask film contains at least one element selected from the group consisting of Ru, Al, Hf, Y, Cr, Nb, Ti, Mo, Ta, and Si.

14. A reflective mask comprising the reflective mask blank according to claim 1, wherein
the phase shift film includes the opening pattern.

15. A method of manufacturing a reflective mask blank, the method comprising:
forming a multilayer reflective film on a substrate, the multilayer reflective film reflecting EUV light; and
forming a phase shift film on the multilayer reflective film, the phase shift film shifting a phase of the EUV light, wherein
an opening pattern is to be formed in the phase shift film, and
the phase shift film has a refractive index of 0.920 or less with respect to the EUV light, an extinction coefficient of 0.024 or more with respect to the EUV light, a thickness of 50 nm or less, a normalized image log slope of 2.9 or more for a transferred image when a line-and-space pattern is formed on a target substrate, and a tolerance range of a focal depth of the transferred image is 60 nm or less.

16. A method of manufacturing a reflective mask, comprising:
preparing the reflective mask blank manufactured by using the method of manufacturing a reflective mask blank according to claim 15; and
forming the opening pattern in the phase shift film.
